(19) United States
(12) Patent Application Publication
(10) Pub. No.: US 2026/0047131 A1
(43) Pub. Date: Feb. 12, 2026

(54) VERTICAL STRUCTURE TRANSISTOR ELEMENT AND METHOD OF MANUFACTURING VERTICAL STRUCTURE TRANSISTOR ELEMENT

(71) Applicant: UIF (University Industry Foundation), Yonsei University, Seoul (KR)

(72) Inventors: Hyun Jae Kim, Seoul (KR); Seok Min Hong, Seoul (KR); Jong Bin An, Seoul (KR); Jusung Chung, Hwaseong-si (KR); Subi Choi, Seoul (KR); Kunho Moon, Seoul (KR)

(21) Appl. No.: 19/290,805

(22) Filed: Aug. 5, 2025

(30) Foreign Application Priority Data
Aug. 6, 2024 (KR) 10-2024-0104357

(51) Int. Cl. H10D 30/67; H10B 12/00; H10D 30/01; H10D 86/40

(52) U.S. Cl. CPC H10D 30/6728; H10D 30/0318; H10D 30/6755; H10D 30/6757; H10D 30/6758; H10D 86/427; H10B 12/00

(57) ABSTRACT

Disclosed is a vertical structure transistor element including a spacer layer made of an insulating material and a thickness-dependent material layer made of a thickness-dependent material that is a material having electrical conductivity changed according to a thickness and stacked on an upper end surface of the spacer layer, wherein the thickness-dependent material layer includes a first electrode area layer stacked on a first upper end surface, a second electrode area layer stacked on a second upper end surface, and a channel area layer stacked on a third upper end surface, and a thickness of the channel area layer is smaller than a thickness of the first electrode area layer and a thickness of the second electrode area layer.

### CROSS-REFERENCE TO RELATED APPLICATIONS

A claim for priority under 35 U.S. C. § 119 is made to Korean Patent Application No. 10-2024-0104357 filed on Aug. 6, 2024, in the Korean Intellectual Property Office, the entire contents of which are hereby incorporated by reference.

### BACKGROUND

Embodiments of the inventive concept described herein relate to a method of manufacturing a vertical structure transistor element capable of increasing integration.

The inventive concept is derived from research conducted as part of development of a core technology of the National Semiconductor Laboratory (NSL) of the Ministry of Science and ICT (Project unique number: 1711197801, Project number: 00256917, Research project name: Development of IGZO V-Tr-based high-integrated/high-performance capacitorless dynamic random access memory (DRAM) technology for next-generation neuromorphic computing systems, Project management agency: Korean research foundation, Project execution agency: Yonsei university industry-academic cooperation foundation, and Research period: 2024.02.01˜2024.12.31). Meanwhile, there is no property interest of the Korean government in all aspects of the inventive concept.

Recently, active research is being conducted in semiconductor element technology to solve the problem of how much power consumption may be reduced.

In the case of vertical structure transistors among transistors that are representative semiconductor elements, the transistors may be manufactured in a narrower space compared to flat structure transistors, contributing to improved integration. In the case of horizontal structure transistors, a channel area is vulnerable to bending, but in the vertical structure transistors, the channel area is vertically formed as compared to the flat structure transistors, and thus is more resistant to bending.

### SUMMARY

Embodiments of the inventive concept provide a vertical structure transistor element capable of improving electrical performance of a transistor by minimizing an overlap area inevitably caused by a vertical structure transistor, and a method of manufacturing a vertical structure transistor element.

Further, embodiments of the inventive concept also provide a vertical structure transistor element that may be used as both an electrode and a channel only by adjusting a thickness of a thin film made of the same material and may implement a vertical structure using a material having electrical conductivity easily adjusted through the adjusting of the thickness, and a method of manufacturing a vertical structure transistor element.

Further, embodiments of the inventive concept also provide a vertical structure transistor element that may be used to produce a high-resolution display and to produce a large-capacity memory by increasing the degree of integration of a transistor, and a method of manufacturing a vertical structure transistor element.

Further, embodiments of the inventive concept also provide a vertical structure transistor element that may be manufactured using a material (e.g., IZO or the like) and equipment (e.g., sputter equipment) used in the existing industries, and a method of manufacturing a vertical structure transistor element.

Further, embodiments of the inventive concept also provide a vertical structure transistor element that may reduce element manufacturing costs by simplifying a process, and a method of manufacturing a vertical structure transistor element.

Meanwhile, the aspects to be achieved in the inventive concept are not limited to the aspects described above, and those skilled in the art to which the inventive concept pertains will clearly understand other aspects not described from the following description.

According to an exemplary embodiment, a vertical structure transistor element includes a spacer layer made of an insulating material and a thickness-dependent material layer made of a thickness-dependent material that is a material having electrical conductivity changed according to a thickness and stacked on an upper end surface of the spacer layer, wherein the spacer layer includes one end area of the upper end surface configured as a first upper end surface, an opposite end area of the upper end surface configured as a second upper end surface, and an area between the first upper end surface and the second upper end surface in the upper end surface configured as a third upper end surface, the thickness-dependent material layer includes a first electrode area layer stacked on the first upper end surface, a second electrode area layer stacked on the second upper end surface, and a channel area layer stacked on the third upper end surface, and a thickness of the channel area layer is smaller than a thickness of the first electrode area layer and a thickness of the second electrode area layer.

Further, the thickness-dependent material layer may be made of one thickness-dependent material among an indium-zinc-oxide (IZO), an indium-gallium-zinc-oxide (IGZO), an indium-oxide (InOx), an indium-tin-oxide (ITO), an indium-zinc-tin-oxide (IZTO), and an indium-gallium-zinc-tin-oxide (IGZTO).

Further, the thickness-dependent material layer may be configured such that the thickness of the channel area layer is smaller than the thickness of the first electrode area layer and the thickness of the second electrode area layer, based on a direction in which the upper end surface of the spacer layer in contact with each area layer is directed.

Further, the spacer layer may be configured such that the second upper end surface is positioned below the first upper end surface and faces the same direction as the first upper end surface and the third upper end surface faces a direction inclined by a reference angle with respect to the first upper end surface and the second upper end surface.

Further, the thickness-dependent material layer may be configured such that the second electrode area layer is positioned below the first electrode area layer and faces the same direction as the first electrode area layer and the channel area layer faces a direction inclined by a reference angle with respect to the first electrode area layer and the second electrode area layer.

Further, the vertical structure transistor element may further include a gate insulator stacked on an upper end of the first electrode area layer, an upper end of the second electrode area layer, and an upper end of the channel area layer and a gate end stacked on an upper end of the gate insulator.

Further, the first electrode area layer may operate as one of a drain end and a source end of the vertical structure transistor element, the second electrode area layer may operate as the source end of the vertical structure transistor element when the first electrode area layer operates as the drain end of the vertical structure transistor element, and the second electrode area layer may operate as the drain end of the vertical structure transistor element when the first electrode area layer operates as the source end of the vertical structure transistor element.

According to an exemplary embodiment, a method of manufacturing a vertical structure transistor element includes generating a spacer layer made of an insulating material and depositing, on an upper end surface of the spacer layer, a thickness-dependent material layer made of a thickness-dependent material that is a material having electrical conductivity changed according to a thickness, wherein the generating of the spacer layer includes forming a first upper end surface that is one end area of the upper end surface, forming a second upper end surface that is an opposite end area of the upper end surface, and forming a third upper end surface that is an area between the first upper end surface and the second upper end surface, and the depositing of the thickness-dependent material layer on the upper end surface of the spacer layer includes depositing the thickness-dependent material on the first upper end surface to form a first electrode area layer, depositing the thickness-dependent material on the second upper end surface to form a second electrode area layer, and depositing the thickness-dependent material on the third upper end surface to form a channel area layer, and forming the first electrode area layer, the second electrode area layer, and the channel area layer such that a thickness of the completely deposited channel area layer is smaller than a thickness of the first electrode area layer and a thickness of the second electrode area layer.

Further, the depositing of the thickness-dependent material layer on the upper end surface of the spacer layer may further include forming the first electrode area layer, the second electrode area layer, and the channel area layer by spraying the thickness-dependent material to the upper end surface of the spacer layer in a sputtering manner.

Further, the depositing of the thickness-dependent material layer on the upper end surface of the spacer layer may further include shooting one thickness-dependent material among an indium-zinc-oxide (IZO), an indium-gallium-zinc-oxide (IGZO), an indium-oxide (InOx), an indium-tin-oxide (ITO), an indium-zinc-tin-oxide (IZTO), and an indium-gallium-zinc-tin-oxide (IGZTO) to the upper end surface of the spacer layer in a sputtering manner.

Further, the depositing of the thickness-dependent material layer on the upper end surface of the spacer layer may further include spraying the thickness-dependent material to the upper end surface of the spacer layer in a sputtering manner such that a thickness of the channel area layer is smaller than a thickness of the first electrode area layer and a thickness of the second electrode area layer, based on a direction in which the upper end surface of the spacer layer in contact with each area layer that is completely deposited is directed.

Further, the generating of the spacer layer may include forming the second upper end surface such that the second upper end surface is positioned below the first upper end surface and faces the same direction as the first upper end surface and forming the third upper end surface such that the third upper end surface faces a direction inclined by a reference angle with respect to the first upper end surface and the second upper end surface.

Further, the depositing of the thickness-dependent material layer on the upper end surface of the spacer layer may further include forming the second electrode area layer such that the second electrode area layer is positioned below the first electrode area layer and faces the same direction as the first electrode area layer and forming the channel area layer such that the channel area layer faces a direction inclined by a reference angle with respect to the first electrode area layer and the second electrode area layer.

Further, the method may further include stacking a gate insulator on an upper end of the first electrode area layer, an upper end of the second electrode area layer, and an upper end of the channel area layer and stacking a gate end on an upper end of the gate insulator.

Further, the completely deposited first electrode area layer may operate as one of a drain end and a source end of the vertical structure transistor element, and the completely deposited second electrode area layer may operate as the source end of the vertical structure transistor element when the first electrode area layer operates as the drain end of the vertical structure transistor element and operate as the drain end of the vertical structure transistor element when the first electrode area layer operates as the source end of the vertical structure transistor element.

According to an exemplary embodiment, a vertical structure dynamic random access memory (DRAM) element includes a first transistor and a second transistor having a gate end electrically connected to one electrode area layer of the first transistor, wherein the first transistor includes a first spacer layer made of an insulating material and a first thickness-dependent material layer made of a thickness-dependent material that is a material having electrical conductivity changed according to a thickness and stacked on an upper end surface of the first spacer layer, wherein the first spacer layer includes one end area of the upper end surface configured as a first upper end surface, an opposite end area of the upper end surface configured as a second upper end surface, and an area between the first upper end surface and the second upper end surface in the upper end surface configured as a third upper end surface, the first thickness-dependent material layer includes a first electrode area layer stacked on the first upper end surface, a second electrode area layer stacked on the second upper end surface, and a first channel area layer stacked on the third upper end surface, a thickness of the first channel area layer is smaller than a thickness of the first electrode area layer and a thickness of the second electrode area layer, the second transistor includes a second spacer layer made of an insulating material and a second thickness-dependent material layer made of the thickness-dependent material and stacked on an upper end surface of the second spacer layer, the second spacer layer includes one end area of the upper end surface configured as a fourth upper end surface, an opposite end area of the upper end surface configured as a fifth upper end surface, and an area between the fourth upper end surface and the fifth upper end surface in the upper end surface configured as a sixth upper end surface, the second thickness-dependent material layer includes a third electrode area layer stacked on the fourth upper end surface, a fourth electrode area layer stacked on the fifth upper end surface, and a second channel area layer stacked on the sixth upper end surface, and a thickness of the second channel area layer is smaller than a thickness of the third electrode area layer and a thickness of the fourth electrode area layer.

Further, the first transistor may further include a first gate insulator stacked on an upper end of the first electrode area layer, an upper end of the second electrode area layer, and an upper end of the first channel area layer and a first gate end stacked on an upper end of the first gate insulator, the second transistor may further include a second gate insulator stacked on an upper end of the third electrode area layer, an upper end of the fourth electrode area layer, and an upper end of the second channel area layer and a second gate end stacked on an upper end of the second gate insulator, and the second electrode area layer may be electrically connected to the second gate end.

Further, the first spacer layer may be configured such that the second upper end surface is positioned below the first upper end surface and faces the same direction as the first upper end surface and the third upper end surface faces a direction inclined by a first reference angle with respect to the first upper end surface and the second upper end surface, and the second spacer layer may be configured such that the fourth upper end surface is positioned above the first upper end surface and faces the same direction as the first upper end surface, the fifth upper end surface is positioned at the same height as the second upper end surface, is positioned below the fourth upper end surface, and faces the same direction as the first upper end surface, the second upper end surface, and the fourth upper end surface, and the sixth upper end surface faces a direction inclined by a second reference angle with respect to the fourth upper end surface and the fifth upper end surface.

Further, the first thickness-dependent material layer may be configured such that the second electrode area layer is positioned below the first electrode area layer and faces the same direction as the first electrode area layer and the first channel area layer faces a direction inclined by a first reference angle with respect to the first electrode area layer and the second electrode area layer, and the second thickness-dependent material layer may be configured such that the third electrode area layer is positioned above the first electrode area layer and faces the same direction as the first electrode area layer, the fourth electrode area layer is positioned below the third electrode area layer and faces the same direction as the third electrode area layer, the second channel area layer faces a direction inclined by a second reference angle with respect to the third electrode area layer and the fourth electrode area layer, and an area of the upper end of the second channel area layer is larger than an area of the upper end of the first channel area layer.

According to an exemplary embodiment, a method of manufacturing a vertical structure DRAM element includes generating a first spacer layer and a second spacer layer made of an insulating material, depositing a first thickness-dependent material layer on an upper end surface of the first spacer layer by spraying a thickness-dependent material, which is a material having electrical conductivity changed according to a thickness, onto the upper end surface of the first spacer layer in a sputtering manner, and depositing a second thickness-dependent material layer on an upper end surface of the second spacer layer by spraying the thickness-dependent material, which is a material having electrical conductivity changed according to a thickness, onto the upper end surface of the second spacer layer in the sputtering manner, wherein the generating of the first spacer layer and the second spacer layer includes forming a first upper end surface that is one end area of the upper end surface of the first spacer layer, forming a second upper end surface that is an opposite end area of the upper end surface of the first spacer layer such that the second upper end surface is positioned below the first upper end surface and faces the same direction as the first upper end surface, forming a third upper end surface that is an area between the first upper end surface and the second upper end surface such that the third upper end surface faces a direction inclined by a first reference angle with respect to the first upper end surface and the second upper end surface, forming a fourth upper end surface that is one end area of the upper end surface of the second spacer layer, forming a fifth upper end surface that is an opposite end area of the upper end surface of the second spacer layer such that the fifth upper end surface is positioned below the fourth upper end surface and faces the same direction as the fourth upper end surface, and forming a sixth upper end surface that is an area between the fourth upper end surface and the fifth upper end surface such that the sixth upper end surface faces a direction inclined by a second reference angle with respect to the fourth upper end surface and the fifth upper end surface, the depositing of the thickness-dependent material layer on the upper end surface of the first spacer layer includes depositing the thickness-dependent material on the first upper end surface to form a first electrode area layer, depositing the thickness-dependent material on the second upper end surface to form a second electrode area layer, and depositing the thickness-dependent material on the third upper end surface to form a first channel area layer, and forming the first electrode area layer, the second electrode area layer, and the first channel area layer such that a thickness of the completely deposited first channel area layer is smaller than a thickness of the first electrode area layer and a thickness of the second electrode area layer, the depositing of the thickness-dependent material layer on the upper end surface of the second spacer layer includes depositing the thickness-dependent material on the fourth upper end surface to form a third electrode area layer, depositing the thickness-dependent material on the fifth upper end surface to form a fourth electrode area layer, and depositing the thickness-dependent material on the sixth upper end surface to form a second channel area layer, and forming the third electrode area layer, the fourth electrode area layer, and the second channel area layer such that a thickness of the completely deposited second channel area layer is smaller than a thickness of the third electrode area layer and a thickness of the fourth electrode area layer, and the method further includes depositing a first gate insulator on an upper end of the first electrode area layer, an upper end of the second electrode area layer, and an upper end of the first channel area layer, depositing a first gate end on an upper end of the first gate insulator, depositing a second gate insulator on an upper end of the third electrode area layer, an upper end of the fourth electrode area layer, and an upper end of the second channel area layer, depositing a second gate end on an upper end of the second gate insulator, and electrically connecting the second electrode area layer to the second gate end.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a view illustrating a vertical structure transistor element according to an embodiment;

FIG. 2 is a cross-sectional view of a vertical structure transistor element according to the embodiment;

FIG. 3 is a cross-sectional view illustrating a transistor element having a vertical structure according to the related art;

FIG. 4 is a view for describing a problem of the transistor element having a vertical structure according to the related art;

FIG. 5 is a graph of an experimental result illustrating an operation of the vertical structure transistor element according to the embodiment;

FIG. 6 is a view for describing a process of generating a spacer layer according to the embodiment;

FIG. 7 is a view for describing a process of generating a thickness-dependent material layer according to the embodiment;

FIG. 8 is a cross-sectional view when the thickness-dependent material layer is actually deposited on the etched spacer layer by a sputtering method;

FIG. 9 is a graph depicting that a thickness-dependent material has a conductivity difference according to a thickness of a thin film according to the embodiment;

FIG. 10 is a view for describing a process of stacking a gate insulator according to the embodiment;

FIG. 11 is a view for describing a process of stacking a gate end according to the embodiment;

FIG. 12 is a circuit diagram illustrating a vertical structure dynamic random access memory (DRAM) element according to the embodiment;

FIG. 13 is a view illustrating the vertical structure DRAM element according to the embodiment; and

FIG. 14 is a cross-sectional view illustrating the vertical structure DRAM element according to the embodiment.

### DETAILED DESCRIPTION

It should be noted in advance that a configuration of the invention for clarifying the solution of the problem to be solved by the inventive concept will be described in detail with reference to the accompanying drawings on the basis of an exemplary embodiment of the inventive concept, the same reference numerals are assigned to the same components even though the components are in different drawings in assigning reference numerals to components of the drawings, and components in other drawings may be cited when necessary in the description of the drawings.

Meanwhile, directional terms such as upward, downward, one side, and an opposite side are used in connection with orientation of the accompanying drawings. Since the components of the embodiment of the inventive concept may be positioned in various orientations, the directional terms are used for illustrative purposes and do not limit the positions thereof.

When a first component “includes” a second component, this means that a third component is not excluded but may be further included unless otherwise specifically stated. When a first component is “connected” to a second component, it may mean that the first component is directly connected to the second component as well as the first component is indirectly connected to the second component with a third component interposed therebetween.

Terms such as first and second are used to distinguish one component from another component, and components are not limited by the above-described terms. Singular expressions include plural expressions unless clearly otherwise indicated in the context.

In each operation, an identification code is used for convenience of description and does not describe a sequence of the operations, and the operations may be performed in a different order from a specified order unless the context clearly states a specific order.

Hereinafter, embodiments of the inventive concept will be described in more detail with reference to the accompanying drawings. The embodiments of the inventive concept may be modified into various forms, and the scope of the inventive concept should not be construed to be limited to the following embodiments. The present embodiments are provided to describe the inventive concept for those skilled in the art more completely. Thus, shapes of the components of the drawings are exaggerated to emphasize a clearer description thereof.

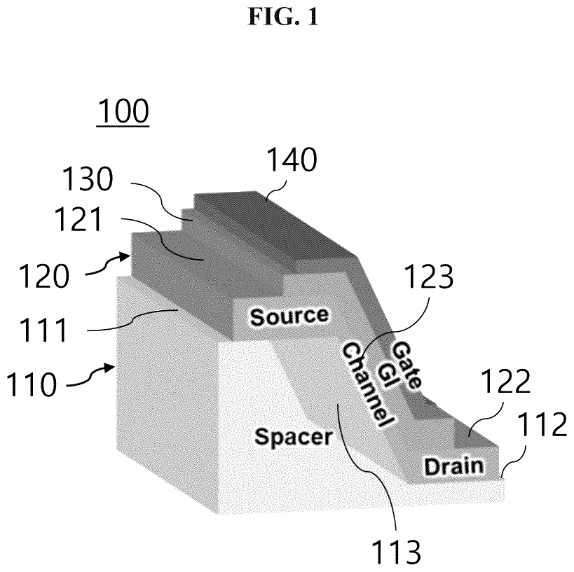

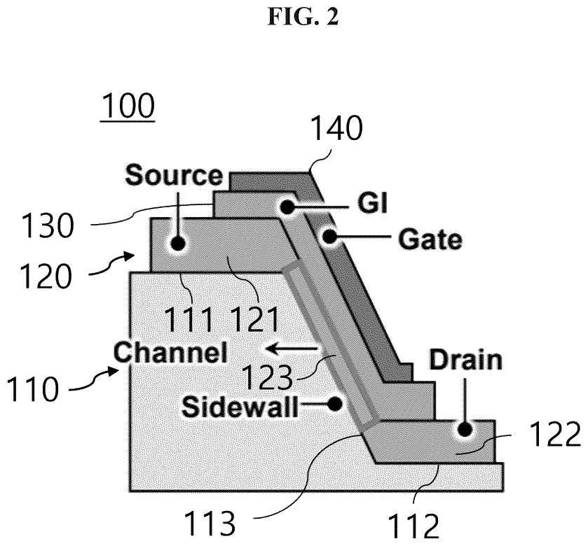

FIG. 1 is a view illustrating a vertical structure transistor element according to an embodiment, and FIG. 2 is a cross-sectional view of a vertical structure transistor element according to the embodiment.

Referring to FIGS. 1 and 2, a vertical structure transistor element 100 may include a spacer layer 110, a thickness-dependent material layer 120, a gate insulator 130, and a gate end 140.

The vertical structure transistor element 100 may be a transistor provided with the gate end 140, a source end, and a drain end and may be a transistor in which the source end and the drain end constitute a layer facing a direction parallel to the ground, and the gate end 140 constitutes a layer facing a direction twisted by a certain angle with respect to the ground.

The spacer layer 110 may be formed of an insulating material. The spacer layer 110 may be formed of a silicon oxide such as SiO₂, but the inventive concept is not limited thereto.

The thickness-dependent material layer 120 may be formed of a thickness-dependent material.

The thickness-dependent material may be a material having electrical conductivity changed according to a thickness. The thickness-and the electrical conductivity increases as the thickness increases. The thickness-dependent material may be a material having high carrier concentration.

In detail, when the thickness-dependent material layer 120 made of the thickness-dependent material has a thickness greater than a certain thickness, the thickness-dependent material layer 120 may be a conductor having little change in current conductivity according to a change in a voltage and may be used as electrodes such as the drain end and the source end. In contrast, when the thickness-dependent material layer 120 made of the thickness-dependent material has a thickness less than the certain thickness, the thickness-dependent material layer 120 may have a characteristic in which little current flows until a voltage is smaller than or equal to a certain voltage and a current flows after the voltage is greater than the certain voltage, and thus may be used as a channel.

The thickness-dependent material layer 120 made of the thickness-dependent material may be stacked on an upper end surface of the spacer layer 110.

One end area of the upper end surface of the spacer layer 110 may be configured as a first upper end surface 111. In this case, the first upper end surface 111 may be horizontal with respect to the ground and may face the same direction as a direction toward which the ground is directed.

An opposite end area of the upper end surface of the spacer layer 110 may be configured as a second upper end surface 112. In this case, the second upper end surface 112 may be horizontal with respect to the ground and may face the same direction as a direction toward which the ground is directed.

An area between the first upper end surface 111 and the second upper end surface 112 on the upper end surface of the spacer layer 110 may be configured as a third upper end surface 113.

The thickness-dependent material layer 120 may include a first electrode area layer 121, a second electrode area layer 122, and a channel area layer 123.

The first electrode area layer 121 may be stacked on the first upper end surface 111 of the spacer layer 110. The second electrode area layer 122 may be stacked on the second upper end surface 112 of the spacer layer 110. The channel area layer 123 may be stacked on the third upper end surface 113 of the spacer layer 110.

A thickness of the first electrode area layer 121 and a thickness of the second electrode area layer 122 may be the same, but the inventive concept is not limited thereto.

The channel area layer 123 may have a thickness smaller than the thickness of the first electrode area layer 121 and the thickness of the second electrode area layer 122.

In this way, the first electrode area layer 121, the second electrode area layer 122, and the channel area layer 123 may be made of the same thickness-dependent material, but the thicknesses thereof may be different from each other. In this case, since the thickness of the channel area layer 123 is smaller than the thickness of the first electrode area layer 121 or the thickness of the second electrode area layer 122, when the first electrode area layer 121 and the second electrode area layer 122 operate as electrodes, the channel area layer 123 may operate as a channel.

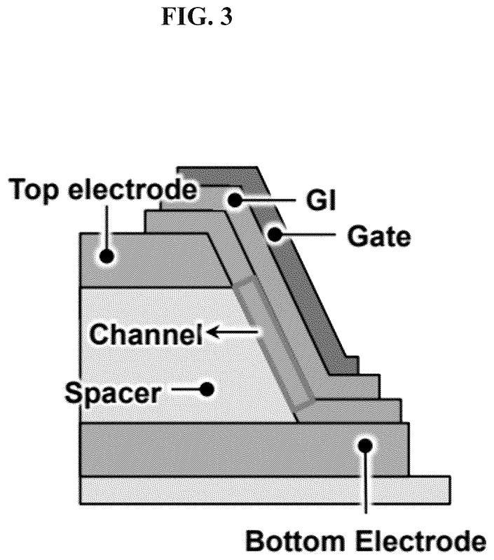

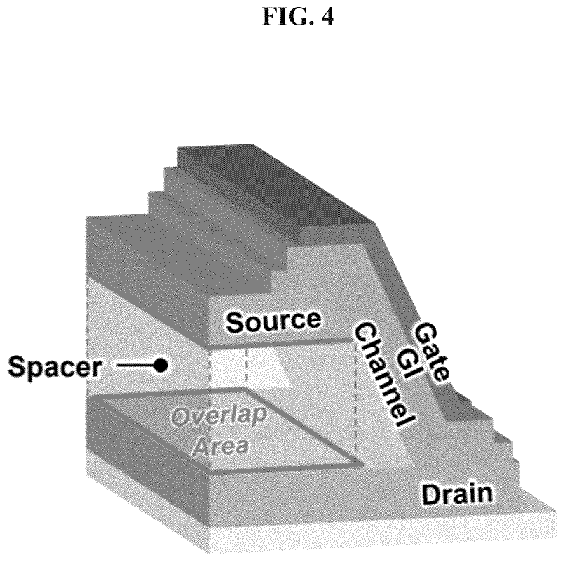

FIG. 3 is a cross-sectional view illustrating a transistor element having a vertical structure according to the related art, and FIG. 4 is a view for describing a problem of the transistor element having a vertical structure according to the related art.

Referring to FIG. 3 and FIG. 4, it may be identified in the vertical structure according to the related art that a drain layer is formed at a lowermost end, a spacer is stacked on an upper end thereof, and a source layer is stacked on an upper end of the spacer. Further, it may be identified that a channel layer is stacked at an upper end of one end of the drain layer, a side surface of the spacer, and a side surface and an upper end of the source layer.

Due to these structural characteristics, a process of manufacturing a vertical structure according to the related art should undergo eight processes including a substrate preparation process, a bottom electrode (BE) deposition process, a spacer deposition process, a top electrode (TE) deposition process, a top electrode and spacer etching for sidewall formation channel deposition process, a gate insulator (GI) deposition process, and a gate deposition process. In the process according to the related art, a process of separately depositing and then etching the BE and the TE is required, and thus the process is complicated.

Further, in an element of the vertical structure according to the related art, an overlap area (OA) is inevitably widened, and thus a z-axis electric field applied to the channel increases. That is, in the element of the vertical structure according to the related art, a normal accumulation layer may not be formed on the channel.

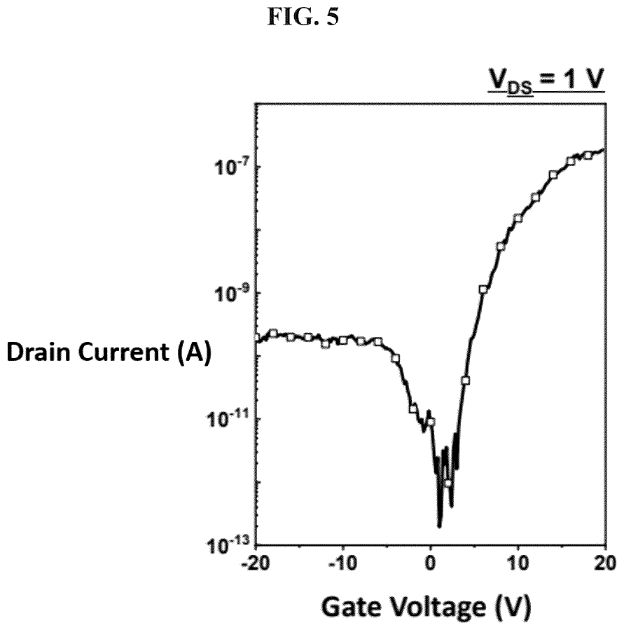

FIG. 5 is a graph of an experimental result illustrating an operation of the vertical structure transistor element according to the embodiment.

Referring to FIG. 5, an experimental result for verifying performance of the vertical structure transistor element 100 of the inventive concept may be identified.

An experiment verified the performance of the vertical structure transistor element 100 that was actually manufactured to include the thickness-dependent material layer 120 made of an indium-zinc-oxide (IZO) as a thickness-dependent material. When the illustrated graph is identified, it may be identified that a vertical structure transistor using the thickness-dependent material layer 120 made of IZO may actually be used as a transistor.

The thickness-dependent material layer 120 may be formed of one thickness-dependent material among an indium-zinc-oxide (IZO), an indium-gallium-zinc-oxide (IGZO), an indium-oxide (InOx), an indium-tin-oxide (ITO), an indium-zinc-tin-oxide (IZTO), and an indium-gallium-zinc-tin-oxide (IGZTO). However, the thickness-dependent material constituting the thickness-dependent material layer 120 is not limited to the above-described materials, and any material may be used as the thickness-dependent material of the inventive concept as long as the material has a characteristic in which electrical conductivity is changed depending on a thickness.

Referring to FIGS. 1, 2, and 5, the thickness-dependent material layer 120 may be configured such that the thickness of the channel area layer 123 is smaller than the thickness of the first electrode area layer 121 and the thickness of the second electrode area layer 122 based on a direction in which the upper end surface of the spacer layer 110 in contact with the area layers is directed.

The second upper end surface 112 of the spacer layer 110 may be positioned below the first upper end surface 111 and may be configured to face the same direction as the first upper end surface 111.

The third upper end surface 113 of the spacer layer 110 may be configured to face a direction inclined by a reference angle with respect to the first upper end surface 111 and the second upper end surface 112. In this case, the reference angle may be a specific angle (e.g., 60 degrees), may be a range of a specific angle (e.g., 40 degrees to 80 degrees), and may be predetermined by a manufacturer depending on a specification and use of an element to be manufactured.

The second electrode area layer 122 of the thickness-dependent material layer 120 may be positioned below the first electrode area layer 121. The second electrode area layer 122 may be configured to face the same direction as the first electrode area layer 121.

The channel area layer 123 of the thickness-dependent material layer 120 may be configured to face a direction inclined by a reference angle with respect to the first electrode area layer 121 and the second electrode area layer 122.

The gate insulator 130 may be stacked on an upper end of the first electrode area layer 121, an upper end of the second electrode area layer 122, and an upper end of the channel area layer 123.

The gate end 140 may be stacked on an upper end of the gate insulator 130.

The first electrode area layer 121 may operate as one of the drain end and the source end of the vertical structure transistor element 100.

When the first electrode area layer 121 operates as the drain end of the vertical structure transistor element 100, the second electrode area layer 122 may operate as the source end of the vertical structure transistor element 100.

When the first electrode area layer 121 operates as the source end of the vertical structure transistor element 100, the second electrode area layer 122 may operate as the drain end of the vertical structure transistor element 100.

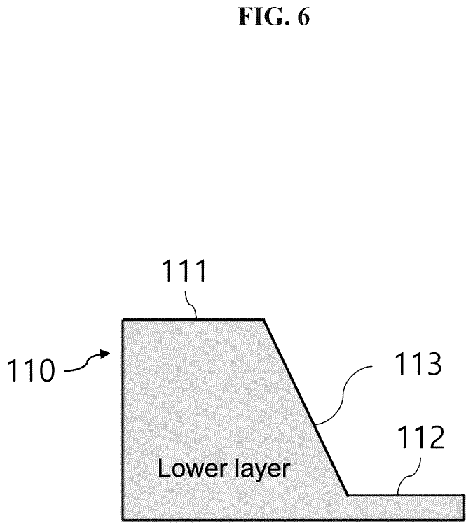

FIG. 6 is a view for describing a process of generating a spacer layer according to the embodiment.

Referring to FIG. 6, a method of manufacturing the vertical structure transistor element 100 may include an operation of generating the spacer layer 110 made of an insulating material.

The spacer layer 110 may be generated through a technique of forming a shape of a side surface through an etching technique such as spacer etching for sidewall formation, but the method of forming the spacer layer 110 is not limited thereto.

The operation of generating the spacer layer 110 may include an operation of forming the first upper end surface 111 that is one end of the upper end surface, forming the second upper end surface 112 that is an opposite end of the upper end surface, and forming the third upper end surface 113 that is an area between the first upper end surface 111 and the second upper end surface 112.

The operation of generating the spacer layer 110 may include an operation of forming the second upper end surface 112 such that the second upper end surface 112 is positioned below the first upper end surface 111 and faces the same direction as the first upper end surface 111.

The operation of generating the spacer layer 110 may include an operation of forming the third upper end surface 113 such that the third upper end surface 113 faces a direction inclined by a reference angle with respect to the first upper end surface 111 and the second upper end surface 112.

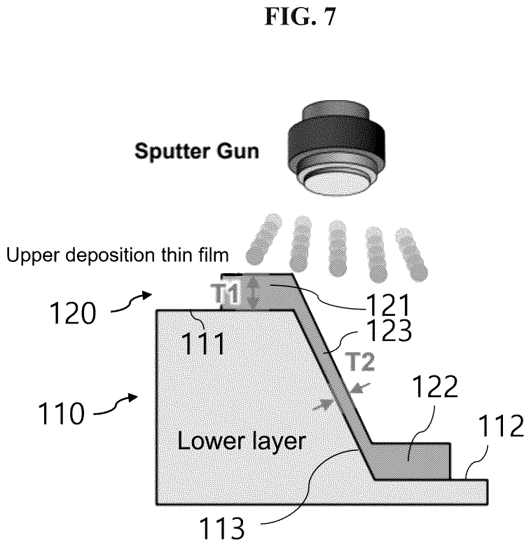

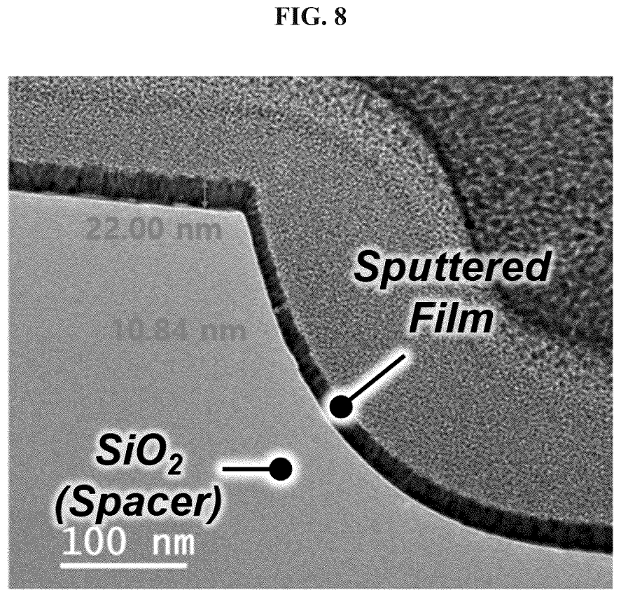

FIG. 7 is a view for describing a process of generating a thickness-dependent material layer according to the embodiment, and FIG. 8 is a cross-sectional view when the thickness-dependent material layer is actually deposited on the etched spacer layer by a sputtering method.

Referring to FIG. 7, the method of manufacturing the vertical structure transistor element 100 may include an operation of depositing the thickness-dependent material layer 120 on the upper end surface of the spacer layer 110.

The operation of depositing the thickness-dependent material layer 120 on the upper end surface of the spacer layer 110 may include an operation of depositing the thickness-dependent material on the first upper end surface 111 to form the first electrode area layer 121, depositing the thickness-dependent material on the second upper end surface 112 to form the second electrode area layer 122, and depositing the thickness-dependent material on the third upper end surface 113 to form the channel area layer 123.

The operation of depositing the thickness-dependent material layer 120 on the upper end surface of the spacer layer 110 may include an operation of forming the first electrode area layer 121, the second electrode area layer 122, and the channel area layer 123 such that the thickness of the completely deposited channel area layer 123 is smaller than the thickness of the first electrode area layer 121 and the thickness of the second electrode area layer 122.

The operation of depositing the thickness-dependent material layer 120 on the upper end surface of the spacer layer 110 may include an operation of spraying the thickness-dependent material onto the upper end surface of the spacer layer 110 in a sputtering manner to form the first electrode area layer 121, the second electrode area layer 122, and the channel area layer 123. In this case, the thickness-dependent material may be shot toward the upper end surface of the spacer layer 110 using a sputter gun.

The sputtering is one of thin film deposition technologies widely used in semiconductor manufacturing processes. This manner is a manner of separating atoms from a target (source material) and depositing the atoms on a substrate. The sputtering may uniformly deposit various materials (metal, insulator, semiconductor, etc.) and thus is widely used in fields such as semiconductors, displays, and solar cells.

A deposition process of the sputtering manner may be performed in a high vacuum state. In this case, a material target to be deposited may be installed in a vacuum chamber. A substrate on which a material to be deposited is placed at a position facing the target, an inert gas such as argon (Ar) may be injected into the vacuum chamber, an electric field may be applied, and thus plasma may be generated. Thereafter, in a sputtering process, ions (cations) of the generated plasma may collide with a surface of the target, the atoms of the target material may be separated, and the separated atoms may be deposited on the substrate.

A main feature of this sputtering is that a thin film may be uniformly formed over a large area, a deposition rate, a thickness, and a material composition may be precisely controlled, and a high-density thin film may be formed.

The operation of depositing the thickness-dependent material layer 120 on the upper end surface of the spacer layer 110 may include an operation of shooting one thickness-dependent material among an indium-zinc-oxide (IZO), an indium-gallium-zinc-oxide (IGZO), an indium-oxide (InOx), an indium-tin-oxide (ITO), an indium-zinc-tin-oxide (IZTO), and an indium-gallium-zinc-tin-oxide (IGZTO) onto the upper end surface of the spacer layer 110 in the sputtering manner.

The operation of depositing the thickness-dependent material layer 120 on the upper end surface of the spacer layer 110 may include an operation of spraying the thickness-dependent material onto the upper end surface of the spacer layer 110 in the sputtering manner such that a thickness T2 of the channel area layer 123 is smaller than a thickness T1 of the first electrode area layer 121 and the thickness T1 of the second electrode area layer 122 based on a direction in which the upper end surface of the spacer layer in contact with each area layer that is completely deposited is directed.

The operation of depositing the thickness-dependent material layer 120 on the upper end surface of the spacer layer 110 may include an operation of forming the second electrode area layer 122 such that the second electrode area layer 122 is positioned below the first electrode area layer 121 and faces the same direction as the first electrode area layer 121.

The operation of depositing the thickness-dependent material layer 120 on the upper end surface of the spacer layer 110 may include an operation of forming the channel area layer 123 such that the channel area layer 123 faces a direction inclined by a reference angle with respect to the first electrode area layer 121 and the second electrode area layer 122.

The completely deposited first electrode area layer 121 may operate as one of the drain end and the source end of the vertical structure transistor element 100.

When the first electrode area layer 121 operates as the drain end of the vertical structure transistor element 100, the completely deposited second electrode area layer 122 may operate as the source end of the vertical structure transistor element 100.

When the first electrode area layer 121 operates as the source end of the vertical structure transistor element 100, the completely deposited second electrode area layer 122 may operate as the drain end of the vertical structure transistor element 100.

Referring to FIGS. 7 and 8, it may be identified that a sputtering manner in which a material deposited to have straightness moves has a lower degree of deposition in a vertical portion than in a horizontal portion. That is, when the thickness-dependent material is evenly shot from an upper end toward a lower side of a shape of the spacer layer 110, in which the first upper end surface 111, the second upper end surface 112, and the third upper end surface 113 are formed, in the sputtering manner, the thickness-dependent material layer 120 may be stacked such that the thickness of the thickness-dependent material stacked at the upper end of the third upper end surface 113 is naturally smaller than the thicknesses of the thickness-dependent materials stacked at the upper ends of the first upper end surface 111 and the second upper end surface 112 due to a structure of the third upper end surface 113 having an inclined surface.

Referring to FIG. 8, an experiment of depositing a material on etched SiO₂ (spacer) using sputtering was performed.

As a result of an experiment in which the material is deposited on a sidewall of the etched SiO₂ (spacer) by the sputtering, it may be identified that there is a difference in the thickness of the material deposited between a vertical portion and a horizontal portion of the sidewall of the SiO₂ (spacer).

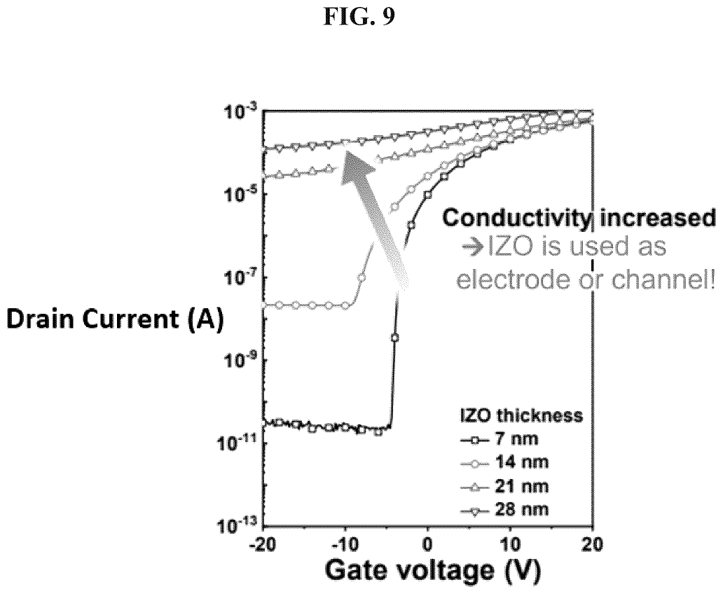

FIG. 9 is a graph depicting that a thickness-dependent material has a conductivity difference according to a thickness of a thin film according to the embodiment.

Referring to FIG. 9, it may be identified that a thin film made of IZO and having a large conductivity difference according to the thickness of the thin film may serve as an electrode because conductivity is high when the thin film is thick, and may exhibit semiconductor characteristics when the thin film is thin. That is, a possibility that a portion serving as an electrode of the transistor and a portion serving as a channel may be simultaneously formed through a single sputtering process using the sputtering manner in which the degrees of deposition of the horizontal portion and the vertical portion are different from each other may be identified. This possibility may be applied not only to the IZO but also to all materials of which electrical conductivity is easily adjusted by adjusting the thickness of the thin film.

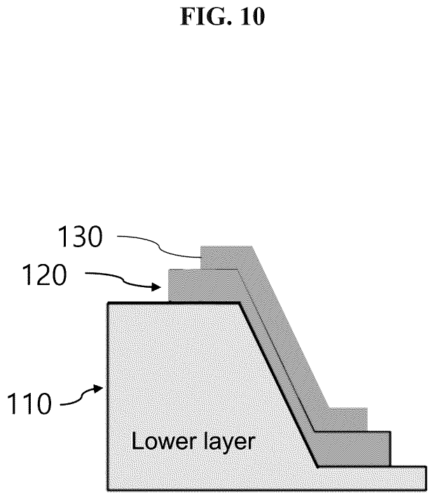

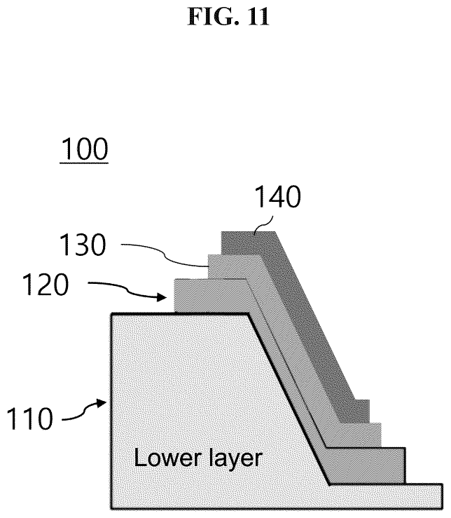

FIG. 10 is a view for describing a process of stacking a gate insulator according to the embodiment, and FIG. 11 is a view for describing a process of stacking a gate end according to the embodiment.

Referring to FIGS. 10 and 11, the method of manufacturing the vertical structure transistor element 100 may include an operation of stacking the gate insulator 130 on the upper end of the first electrode area layer 121, the upper end of the second electrode area layer 122, and the upper end of the channel area layer 123.

In this case, the stacking of the gate insulator 130 may be depositing the gate insulator (GI) 130 in an atomic layer deposition (ALD) manner, but the stacking of the gate insulator 130 is not limited thereto. The gate insulator 130 may be an insulating layer positioned between the gate electrode and the channel in a metal-oxide-semiconductor field-effect transistor (MOSFET).

The method of manufacturing the vertical structure transistor element 100 may further include an operation of stacking the gate end 140 on the upper end of the gate insulator 130. The gate end 140 may be formed by being patterned through an exposure process and then depositing a metal through a deposition technique such as an E-beam evaporator, but a manner of stacking the gate end 140 is not limited thereto.

According to the above-described process manner, the number of processes may be reduced compared to a process manner of manufacturing a vertical element structure according to the related art.

In the related art, a substrate (SiO2/p+—Si) preparation process, a drain deposition process, a spacer deposition process, a source deposition process, a source & spacer etching for sidewall formation process, a channel deposition process, a GI deposition process, and a gate deposition process were required.

On the other hand, the vertical structure transistor process proposed in the inventive concept requires the substrate (SiO2/p+—Si) preparation process, the spacer etching for sidewall formation process, a one-step deposition (drain, source, and channel) process, a GI deposition process, and a gate deposition process, and thus the number of processes may be significantly reduced as compared to the related art.

A vertical structure transistor mechanism of the inventive concept may deposit a thin film having a thickness difference between the horizontal portion and a sidewall portion at once through sputtering having straightness of a deposition material. In this case, the layer deposited at one time is a thin film having a large difference in conductivity according to the thickness and may be used simultaneously as a channel and an electrode. A vertical structure transistor in which the thin film deposited on the sidewall portion is used as the channel and the thick film disposed on the horizontal portion is used as the electrode may be manufactured. That is, the electrode and the channel may be deposited in a single sputtering process, and thus the process may be very simple compared to the vertical structure transistor according to the related art.

Due to the structure of the vertical structure transistor element 100, the OA may be removed, and thus a phenomenon such as an increase in subthreshold swing (S.S.) caused by the OA may not occur.

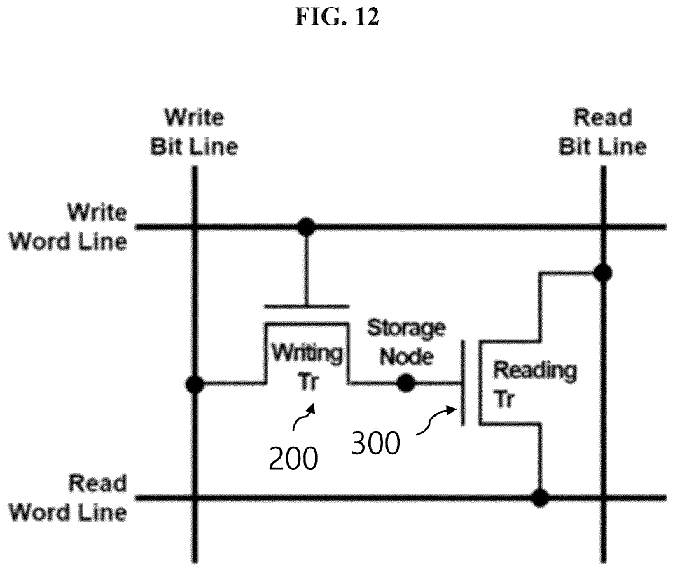

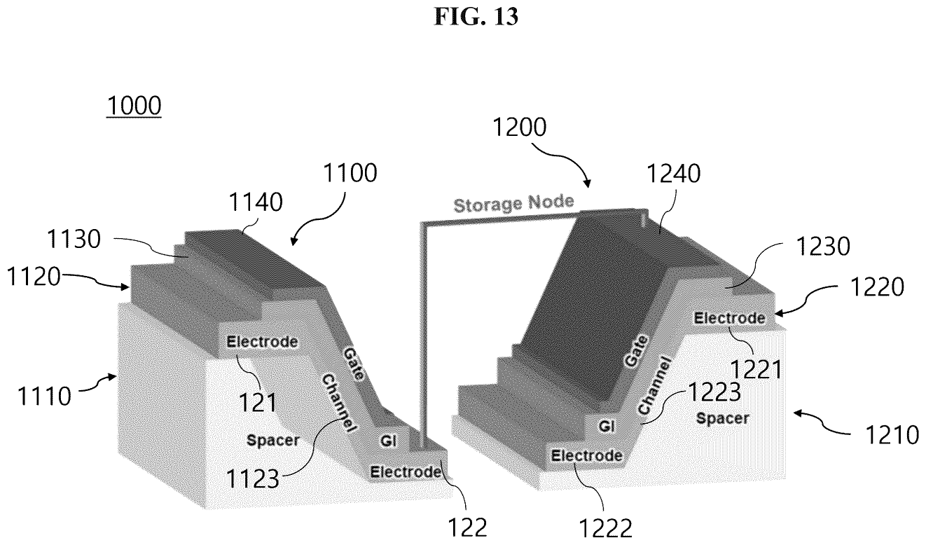

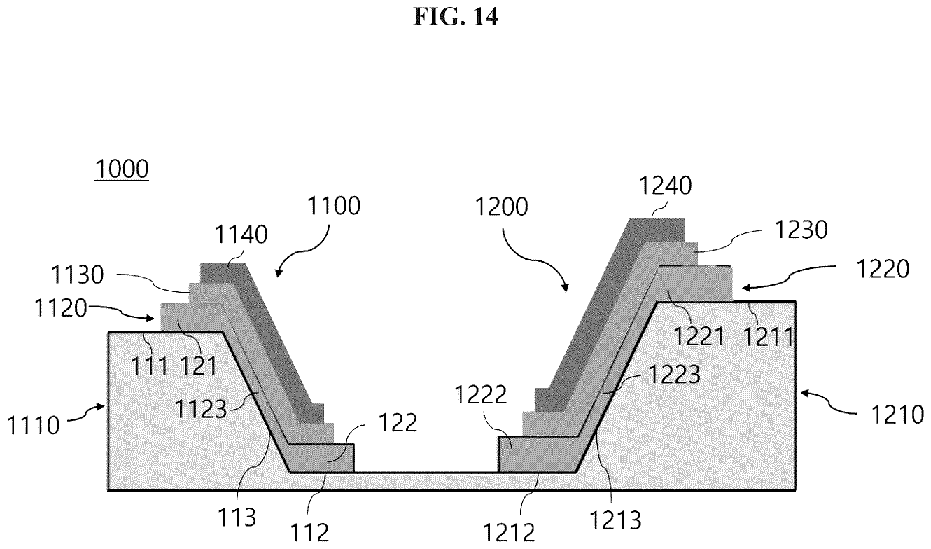

FIG. 12 is a circuit diagram illustrating a vertical structure dynamic random access memory (DRAM) element according to the embodiment, FIG. 13 is a view illustrating the vertical structure DRAM element according to the embodiment, and FIG. 14 is a cross-sectional view illustrating the vertical structure DRAM element according to the embodiment.

Referring to FIGS. 12, 13, and 14, a vertical structure DRAM element 1000 may include a first transistor 1100 and a second transistor 1200. Each of the first transistor 1100 and the second transistor 1200 may be the vertical structure transistor element 100 of the inventive concept.

The second transistor 1200 may be provided with the gate end 140 electrically connected to any one electrode area layer of the first transistor 1100.

The first transistor 1100 may include a first spacer layer 1110 and a first thickness-dependent material layer 1120.

The first spacer layer 1110 may be formed of an insulating material.

The first thickness-dependent material layer 1120 may be formed of a thickness-dependent material that is a material having a characteristic in which electrical conductivity is changed according to the thickness. The first thickness-dependent material layer 1120 may be stacked on an upper end surface of the first spacer layer 1110.

One end area of the upper end surface of the first spacer layer 1110 may be configured as the first upper end surface 111. An opposite end area of the upper end surface of the first spacer layer 1110 may be configured as the second upper end surface 112. An area between the first upper end surface 111 and the second upper end surface 112 on the upper end surface of the first spacer layer 1110 may be configured as the third upper end surface 113.

The first thickness-dependent material layer 1120 may include the first electrode area layer 121, the second electrode area layer 122, and a first channel area layer 1123.

The first electrode area layer 121 may be stacked on the first upper end surface 111. The second electrode area layer 122 may be stacked on the second upper end surface 112. The first channel area layer 1123 may be stacked on the third upper end surface 113.

The first thickness-dependent material layer 1120 may be configured such that a thickness of the first channel area layer 1123 is smaller than the thickness of the first electrode area layer 121 and the thickness of the second electrode area layer 122.

The second transistor 1200 may include a second spacer layer 1210 and a second thickness-dependent material layer 1220.

The second spacer layer 1210 may be formed of an insulating material.

The second thickness-dependent material layer 1220 may be formed of a thickness-dependent material. The second thickness-dependent material layer 1220 may be stacked on an upper end surface of the second spacer layer 1210.

One end area of the upper end surface of the second spacer layer 1210 may be configured as a fourth upper end surface 1211.

An opposite end area of the upper end surface of the second spacer layer 1210 may be configured as a fifth upper end surface 1212.

An area between the fourth upper end surface 1211 and the fifth upper end surface 1212 on the upper end surface of the second spacer layer 1210 may be configured as a sixth upper end surface 1213.

The second thickness-dependent material layer 1220 may include a third electrode area layer 1221, a fourth electrode area layer 1222, and a second channel area layer 1223.

The third electrode area layer 1221 may be stacked on the fourth upper end surface 1211. The fourth electrode area layer 1222 may be stacked on the fifth upper end surface 1212.

The second channel area layer 1223 may be stacked on the sixth upper end surface 1213. The second thickness-dependent material layer 1220 may be configured such that a thickness of the second channel area layer 1223 is smaller than a thickness of the third electrode area layer 1221 and a thickness of the fourth electrode area layer 1222.

The first transistor 1100 may include a first gate insulator 1130 and a first gate end 1140.

The first gate insulator 1130 may be stacked on the upper end of the first electrode area layer 121, the upper end of the second electrode area layer 122, and an upper end of the first channel area layer 1123.

The first gate end 1140 may be stacked on an upper end of the first gate insulator 1130.

The second transistor 1200 may include a second gate insulator 1230 and a second gate end 1240.

The second gate insulator 1230 may be stacked on an upper end of the third electrode area layer 1221, an upper end of the fourth electrode area layer 1222, and an upper end of the second channel area layer 1223.

The second gate end 1240 may be stacked on an upper end of the second gate insulator 1230.

The second electrode area layer 122 may be electrically connected to the second gate end 1240.

The first spacer layer 1110 may be configured such that the second upper end surface 112 is positioned below the first upper end surface 111 and faces the same direction as the first upper end surface 111.

The first spacer layer 1110 may be configured such that the third upper end surface 113 faces a direction inclined by a first reference angle with respect to the first upper end surface 111 and the second upper end surface 112.

The first reference angle may be a specific angle (e.g., 60 degrees), may be a range of a specific angle (e.g., 40 degrees to 80 degrees), and may be predetermined by a manufacturer depending on a specification and use of an element to be manufactured.

The second spacer layer 1210 may be configured such that the fourth upper end surface 1211 is positioned above the first upper end surface 111 and faces the same direction as the first upper end surface 111.

The second spacer layer 1210 may be configured such that the fifth upper end surface 1212 is positioned at the same height with respect to the second upper end surface 112, is positioned below the fourth upper end surface 1211, and faces the same direction as the first upper end surface 111, the second upper end surface 112, and the fourth upper end surface 1211.

The second spacer layer 1210 may be configured such that the sixth upper end surface 1213 faces a direction inclined by a second reference angle with respect to the fourth upper end surface 1211 and the fifth upper end surface 1212.

The second reference angle may be a specific angle (e.g., 60 degrees), may be a range of a specific angle (e.g., 40 degrees to 80 degrees), and may be predetermined by a manufacturer depending on a specification and use of an element to be manufactured.

The first thickness-dependent material layer 1120 may be configured such that the second electrode area layer 122 is positioned below the first electrode area layer 121 and faces the same direction as the first electrode area layer 121.

The first thickness-dependent material layer 1120 may be configured such that the first channel area layer 1123 faces a direction inclined by the first reference angle with respect to the first electrode area layer 121 and the second electrode area layer 122.

The second thickness-dependent material layer 1220 may be configured such that the third electrode area layer 1221 is positioned above the first electrode area layer 121 and faces the same direction as the first electrode area layer 121.

The second thickness-dependent material layer 1220 may be configured such that the fourth electrode area layer 1222 is positioned below the third electrode area layer 1221 and faces the same direction as the third electrode area layer 1221.

The second thickness-dependent material layer 1220 may be configured such that the second channel area layer 1223 faces a direction inclined by the second reference angle with respect to the third electrode area layer 1221 and the fourth electrode area layer 1222.

Meanwhile, it is preferable that a channel area of the second transistor 1200 is wider than that of the first transistor 1100 due to characteristics of a DRAM cell.

The second thickness-dependent material layer 1220 may be configured such that an area of the upper end of the second channel area layer 1223 is larger than an area of the upper end of the first channel area layer 1123.

A method of manufacturing the vertical structure DRAM element 1000 may include an operation of generating the first spacer layer 1110 and the second spacer layer 1210 made of an insulating material, an operation of depositing the first thickness-dependent material layer 1120 on the upper end surface of the first spacer layer 1110, and an operation of depositing the second thickness-dependent material layer 1220 on the upper end surface of the second spacer layer 1210.

The operation of depositing the first thickness-dependent material layer 1120 on the upper end surface of the first spacer layer 1110 may include an operation of spraying a thickness-dependent material, which is a material having electrical conductivity changed depending on a thickness, onto the upper end surface of the first spacer layer 1110 in a sputtering manner.

The operation of depositing the second thickness-dependent material layer 1220 on the upper end surface of the second spacer layer 1210 may include an operation of spraying a thickness-dependent material, which is a material having electrical conductivity changed depending on a thickness, onto the upper end surface of the second spacer layer 1210 in a sputtering manner.

The operation of generating the first spacer layer 1110 and the second spacer layer 1210 may include an operation of forming the first upper end surface 111, an operation of forming the second upper end surface 112, an operation of forming the third upper end surface 113, an operation of forming the fourth upper end surface 1211, an operation of forming the fifth upper end surface 1212 and an operation of forming the sixth upper end surface 1213.

The operation of forming the fifth upper end surface 1212 may be an operation of forming the fifth upper end surface 1212, which is the opposite end area of the upper end surface of the second spacer layer 1210, such that the fifth upper end surface 1212 is positioned below the fourth upper end surface 1211 and faces the same direction as the fourth upper end surface 1211.

The operation of forming the sixth upper end surface 1213 may be an operation of forming the sixth upper end surface 1213, which is an area between the fourth upper end surface 1211 and the fifth upper end surface 1212, such that the sixth upper end surface 1213 faces the direction inclined by the second reference angle with respect to the fourth upper end surface 1211 and the fifth upper end surface 1212.

The operation of depositing the thickness-dependent material layer 120 on the upper end surface of the first spacer layer 1110 may include an operation of depositing the thickness-dependent material on the first upper end surface 111 to form the first electrode area layer 121, depositing the thickness-dependent material on the second upper end surface 112 to form the second electrode area layer 122, and depositing the thickness-dependent material on the third upper end surface 113 to form the first channel area layer 1123.

The operation of depositing the thickness-dependent material layer 120 on the upper end surface of the first spacer layer 1110 may include an operation of forming the first electrode area layer 121, the second electrode area layer 122, and the first channel area layer 1123 such that the thickness of the completely deposited first channel area layer 1123 is smaller than the thickness of the first electrode area layer 121 and the thickness of the second electrode area layer 122.

The operation of depositing the thickness-dependent material layer 120 on the upper end surface of the second spacer layer 1210 may include an operation of depositing the thickness-dependent material on the fourth upper end surface 1211 to form the third electrode area layer 1221, depositing the thickness-dependent material on the fifth upper end surface 1212 to form the fourth electrode area layer 1222, and depositing the thickness-dependent material on the sixth upper end surface 1213 to form the second channel area layer 1223.

The operation of depositing the thickness-dependent material layer 120 on the upper end surface of the second spacer layer 1210 may include an operation of forming the third electrode area layer 1221, the fourth electrode area layer 1222, and the second channel area layer 1223 such that the thickness of the completely deposited second channel area layer 1223 is smaller than the thickness of the third electrode area layer 1221 and the thickness of the fourth electrode area layer 1222.

The method of manufacturing the vertical structure DRAM element 1000 may include an operation of depositing the first gate insulator 1130 on the upper end of the first electrode area layer 121, the upper end of the second electrode area layer 122, and the upper end of the first channel area layer 1123.

The method of manufacturing the vertical structure DRAM element 1000 may include an operation of depositing the first gate end 1140 on the upper end of the first gate insulator 1130.

The method of manufacturing the vertical structure DRAM element 1000 may include an operation of depositing the second gate insulator 1230 on the upper end of the third electrode area layer 1221, the upper end of the fourth electrode area layer 1222, and the upper end of the second channel area layer 1223.

The method of manufacturing the vertical structure DRAM element 1000 may include an operation of depositing the second gate end 1240 on the upper end of the second gate insulator 1230.

The method of manufacturing the vertical structure DRAM element 1000 may further include an operation of electrically connecting the second electrode area layer 122 to the second gate end 1240. In this case, the operation of electrically connecting the second electrode area layer 122 to the second gate end 1240 may be a manner of depositing a conductor material such that the conductor material is in contact with both the upper end of the second electrode area layer 122 and an upper end of the second gate end 1240, but the inventive concept is not limited thereto.

According to an aspect of the inventive concept, electrical performance of a transistor may be improved by minimizing an overlap area that is inevitably caused by a vertical structure transistor.

According to another aspect of the inventive concept, a vertical structure may be used as both an electrode and a channel only by adjusting a thickness of a thin film made of the same material and may be implemented using a material having conductivity that is easily adjusted by adjusting the thickness.

According to still another aspect of the inventive concept, by increasing the degree of integration of a transistor, a high-resolution display may be produced and a large-capacity memory may be produced.

According to yet another aspect of the inventive concept, a vertical structure transistor element may be manufactured using a material (IZO, etc.) and equipment (sputter equipment) used in existing industries.

According to yet aspect of the inventive concept, a process may be simplified, and thus element manufacturing costs may be reduced.

Meanwhile. the effects obtained in the inventive concept are not limited to the effects described above, and other effects not described will be clearly understood by those skilled in the art to which the inventive concept pertains from the following description.

The above detailed description exemplifies the inventive concept. Furthermore, the above-mentioned contents describe the embodiments of the inventive concept, and the inventive concept may be used in various other combinations, changes, and environments. That is, the inventive concept may be modified and corrected without departing from the scope of the inventive concept that is disclosed in the specification, the equivalent scope to the written disclosures, and/or the technical or knowledge range of those skilled in the art. The written embodiment describes the best state for implementing the technical spirit of the inventive concept, and various changes required in the detailed application fields and purposes of the inventive concept may be made. Thus, the above detailed description of the inventive concept is not intended to restrict the inventive concept in an embodiment. Furthermore, it should be construed that the appended claims include an embodiment.

What is claimed is:

1. A vertical structure transistor element comprising:
a spacer layer made of an insulating material; and
a thickness-dependent material layer made of a thickness-dependent material that is a material having electrical conductivity changed according to a thickness and stacked on an upper end surface of the spacer layer,
wherein the spacer layer includes:
one end area of the upper end surface configured as a first upper end surface;
an opposite end area of the upper end surface configured as a second upper end surface; and
an area between the first upper end surface and the second upper end surface in the upper end surface configured as a third upper end surface,
wherein the thickness-dependent material layer includes:
a first electrode area layer stacked on the first upper end surface;
a second electrode area layer stacked on the second upper end surface; and
a channel area layer stacked on the third upper end surface, and
wherein a thickness of the channel area layer is smaller than a thickness of the first electrode area layer and a thickness of the second electrode area layer.

2. The vertical structure transistor element of claim 1, wherein the thickness-dependent material layer is made of one thickness-dependent material among an indium-zinc-oxide (IZO), an indium-gallium-zinc-oxide (IGZO), an indium-oxide (InOx), an indium-tin-oxide (ITO), an indium-zinc-tin-oxide (IZTO), and an indium-gallium-zinc-tin-oxide (IGZTO).

3. The vertical structure transistor element of claim 1, wherein the thickness-dependent material layer is configured such that the thickness of the channel area layer is smaller than the thickness of the first electrode area layer and the thickness of the second electrode area layer, based on a direction in which the upper end surface of the spacer layer in contact with each area layer is directed.

4. The vertical structure transistor element of claim 3, wherein the spacer layer is configured such that:
the second upper end surface is positioned below the first upper end surface and faces the same direction as the first upper end surface; and
the third upper end surface faces a direction inclined by a reference angle with respect to the first upper end surface and the second upper end surface.

5. The vertical structure transistor element of claim 4, wherein the thickness-dependent material layer is configured such that:
the second electrode area layer is positioned below the first electrode area layer and faces the same direction as the first electrode area layer; and
the channel area layer faces a direction inclined by a reference angle with respect to the first electrode area layer and the second electrode area layer.

6. The vertical structure transistor element of claim 5, further comprising:
a gate insulator stacked on an upper end of the first electrode area layer, an upper end of the second electrode area layer, and an upper end of the channel area layer; and
a gate end stacked on an upper end of the gate insulator.

7. The vertical structure transistor element of claim 6, wherein the first electrode area layer operates as one of a drain end and a source end of the vertical structure transistor element,
wherein the second electrode area layer operates as the source end of the vertical structure transistor element when the first electrode area layer operates as the drain end of the vertical structure transistor element, and
wherein the second electrode area layer operates as the drain end of the vertical structure transistor element when the first electrode area layer operates as the source end of the vertical structure transistor element.

8. A method of manufacturing a vertical structure transistor element, the method comprising:
generating a spacer layer made of an insulating material; and
depositing, on an upper end surface of the spacer layer, a thickness-dependent material layer made of a thickness-dependent material that is a material having electrical conductivity changed according to a thickness,
wherein the generating of the spacer layer includes:
forming a first upper end surface that is one end area of the upper end surface, forming a second upper end surface that is an opposite end area of the upper end surface, and forming a third upper end surface that is an area between the first upper end surface and the second upper end surface, and
wherein the depositing of the thickness-dependent material layer on the upper end surface of the spacer layer includes:
depositing the thickness-dependent material on the first upper end surface to form a first electrode area layer, depositing the thickness-dependent material on the second upper end surface to form a second electrode area layer, and depositing the thickness-dependent material on the third upper end surface to form a channel area layer; and
forming the first electrode area layer, the second electrode area layer, and the channel area layer such that a thickness of the completely deposited channel area layer is smaller than a thickness of the first electrode area layer and a thickness of the second electrode area layer.

9. The method of claim 8, wherein the depositing of the thickness-dependent material layer on the upper end surface of the spacer layer further includes:
forming the first electrode area layer, the second electrode area layer, and the channel area layer by spraying the thickness-dependent material to the upper end surface of the spacer layer in a sputtering manner.

10. The method of claim 9, wherein the depositing of the thickness-dependent material layer on the upper end surface of the spacer layer further includes:
shooting one thickness-dependent material among an indium-zinc-oxide (IZO), an indium-gallium-zinc-oxide (IGZO), an indium-oxide (InOx), an indium-tin-oxide (ITO), an indium-zinc-tin-oxide (IZTO), and an indium-gallium-zinc-tin-oxide (IGZTO) to the upper end surface of the spacer layer in a sputtering manner.

11. The method of claim 9, wherein the depositing of the thickness-dependent material layer on the upper end surface of the spacer layer further includes:
spraying the thickness-dependent material to the upper end surface of the spacer layer in a sputtering manner such that a thickness of the channel area layer is smaller than a thickness of the first electrode area layer and a thickness of the second electrode area layer, based on a direction in which the upper end surface of the spacer layer in contact with each area layer that is completely deposited is directed.

12. The method of claim 11, wherein the generating of the spacer layer includes:
forming the second upper end surface such that the second upper end surface is positioned below the first upper end surface and faces the same direction as the first upper end surface; and
forming the third upper end surface such that the third upper end surface faces a direction inclined by a reference angle with respect to the first upper end surface and the second upper end surface.

13. The method of claim 12, wherein the depositing of the thickness-dependent material layer on the upper end surface of the spacer layer further includes:
forming the second electrode area layer such that the second electrode area layer is positioned below the first electrode area layer and faces the same direction as the first electrode area layer; and
forming the channel area layer such that the channel area layer faces a direction inclined by a reference angle with respect to the first electrode area layer and the second electrode area layer.

14. The method of claim 13, further comprising:
stacking a gate insulator on an upper end of the first electrode area layer, an upper end of the second electrode area layer, and an upper end of the channel area layer; and
stacking a gate end on an upper end of the gate insulator.

15. The method of claim 14, wherein the completely deposited first electrode area layer operates as one of a drain end and a source end of the vertical structure transistor element, and
wherein the completely deposited second electrode area layer is configured to:
operate as the source end of the vertical structure transistor element when the first electrode area layer operates as the drain end of the vertical structure transistor element; and
operate as the drain end of the vertical structure transistor element when the first electrode area layer operates as the source end of the vertical structure transistor element.

16. A vertical structure dynamic random access memory (DRAM) element comprising:
a first transistor; and
a second transistor having a gate end electrically connected to one electrode area layer of the first transistor,
wherein the first transistor includes:
a first spacer layer made of an insulating material; and
a first thickness-dependent material layer made of a thickness-dependent material that is a material having electrical conductivity changed according to a thickness and stacked on an upper end surface of the first spacer layer,
wherein the first spacer layer includes:
one end area of the upper end surface configured as a first upper end surface;
an opposite end area of the upper end surface configured as a second upper end surface; and
an area between the first upper end surface and the second upper end surface in the upper end surface configured as a third upper end surface,
wherein the first thickness-dependent material layer includes:
a first electrode area layer stacked on the first upper end surface;
a second electrode area layer stacked on the second upper end surface; and
a first channel area layer stacked on the third upper end surface,
wherein a thickness of the first channel area layer is smaller than a thickness of the first electrode area layer and a thickness of the second electrode area layer,
wherein the second transistor includes:
a second spacer layer made of an insulating material; and
a second thickness-dependent material layer made of the thickness-dependent material and stacked on an upper end surface of the second spacer layer,
wherein the second spacer layer includes:
one end area of the upper end surface configured as a fourth upper end surface;
an opposite end area of the upper end surface configured as a fifth upper end surface; and
an area between the fourth upper end surface and the fifth upper end surface in the upper end surface configured as a sixth upper end surface,
wherein the second thickness-dependent material layer includes:
a third electrode area layer stacked on the fourth upper end surface;
a fourth electrode area layer stacked on the fifth upper end surface; and
a second channel area layer stacked on the sixth upper end surface, and
wherein a thickness of the second channel area layer is smaller than a thickness of the third electrode area layer and a thickness of the fourth electrode area layer.

17. The vertical structure DRAM element of claim 16, wherein the first transistor further includes:
a first gate insulator stacked on an upper end of the first electrode area layer, an upper end of the second electrode area layer, and an upper end of the first channel area layer; and
a first gate end stacked on an upper end of the first gate insulator,
wherein the second transistor further includes:
a second gate insulator stacked on an upper end of the third electrode area layer, an upper end of the fourth electrode area layer, and an upper end of the second channel area layer; and
a second gate end stacked on an upper end of the second gate insulator, and
wherein the second electrode area layer is electrically connected to the second gate end.

18. The vertical structure DRAM element of claim 17, wherein the first spacer layer is configured such that:
the second upper end surface is positioned below the first upper end surface and faces the same direction as the first upper end surface; and
the third upper end surface faces a direction inclined by a first reference angle with respect to the first upper end surface and the second upper end surface, and
wherein the second spacer layer is configured such that:
the fourth upper end surface is positioned above the first upper end surface and faces the same direction as the first upper end surface;
the fifth upper end surface is positioned at the same height as the second upper end surface, is positioned below the fourth upper end surface, and faces the same direction as the first upper end surface, the second upper end surface, and the fourth upper end surface; and
the sixth upper end surface faces a direction inclined by a second reference angle with respect to the fourth upper end surface and the fifth upper end surface.

19. The vertical structure DRAM element of claim 18, wherein the first thickness-dependent material layer is configured such that:
the second electrode area layer is positioned below the first electrode area layer and faces the same direction as the first electrode area layer; and
the first channel area layer faces a direction inclined by a first reference angle with respect to the first electrode area layer and the second electrode area layer, and
wherein the second thickness-dependent material layer is configured such that:
the third electrode area layer is positioned above the first electrode area layer and faces the same direction as the first electrode area layer;
the fourth electrode area layer is positioned below the third electrode area layer and faces the same direction as the third electrode area layer;
the second channel area layer faces a direction inclined by a second reference angle with respect to the third electrode area layer and the fourth electrode area layer; and
an area of the upper end of the second channel area layer is larger than an area of the upper end of the first channel area layer.
